(19) United States
(12) Patent Application Publication
(10) Pub. No.: US 2025/0193997 A1
(43) Pub. Date: Jun. 12, 2025

(54) MULTILAYER WIRING SUBSTRATE AND SEMICONDUCTOR PACKAGE INCLUDING THE MULTILAYER WIRING SUBSTRATE

(71) Applicant: Samsung Electronics Co., Ltd., Suwon-si (KR)

(72) Inventors: Seokbeom Yong, Suwon-si (KR); Eunkyeong Park, Suwon-si (KR); Sangsub Song, Suwon-si (KR); Seulgi Yu, Suwon-si (KR)

(21) Appl. No.: 18/958,209

(22) Filed: Nov. 25, 2024

(30) Foreign Application Priority Data
Dec. 11, 2023 (KR) 10-2023-0178952

(51) Int. Cl. H05K 1/02; H01L 23/00; H01L 23/31; H01L 23/498; H05K 1/11; H05K 1/18

(52) U.S. Cl. CPC H05K 1/0242; H01L 23/49816; H01L 23/49822; H01L 23/49838; H01L 24/16; H05K 1/025; H05K 1/111; H05K 1/181; H01L 23/3135; H01L 24/08; H01L 2224/16227; H01L 2924/3011; H05K 2201/10674; H05K 2201/10734

(57) ABSTRACT

A multilayer wiring substrate includes insulating layers sequentially stacked on each other, each having an upper surface and a lower surface opposite to the upper surface, circuit layers sequentially stacked and respectively provided in the insulating layers, and each having wirings, and lower substrate pads included in the bottommost circuit layer and exposed from the lower surface of the insulating layers, each of the lower substrate pads being electrically connected to the wirings of a circuit layer above the lower substrate pad, the lower substrate pads including a signal ball landing pad. At least one circuit layer includes a ground conductive layer at a higher vertical level than the signal ball landing pad and having an opening in a region corresponding to the signal ball landing pad, and a signal pattern within the opening and electrically connected to the signal ball landing pad.

### PRIORITY STATEMENT

This application claims priority under 35 U.S.C. § 119 to Korean Patent Application No. 10-2023-0178952, filed on Dec. 11, 2023 in the Korean Intellectual Property Office (KIPO), the contents of which are herein incorporated by reference in their entirety.

### BACKGROUND

### 1. Field

Example embodiments relate to a multilayer wiring substrate and a semiconductor package including the multilayer wiring substrate. More particularly, example embodiments relate to a multilayer wiring substrate configured to transmit high-speed signals to a semiconductor chip mounted thereon and a semiconductor package including the same.

### 2. Description of the Related Art

In signal transmission through a package substrate to an integrated circuit die mounted on the package substrate, impedance characteristics become more important as the signal transmission speed increases. For example, when a signal is transmitted through a ball landing pad, since the ball landing pad is relatively large, the impedance of the ball landing pad may be drastically lowered by capacitive coupling between the ball landing pad and a ground plane, and accordingly, signal reflection may occur, insertion loss at high frequencies may increase, and signal quality may deteriorate.

In order to reduce the capacitance between the ball landing pad and the ground wiring, an anti-pad structure may be provided by removing a portion of the ground wiring on the ball landing pad. However, voids may be generated in a dielectric layer on the ball landing pad, and the resulting cracks may progress upward along the dielectric layer to damage a portion of a trace, thereby reducing reliability.

### SUMMARY

Example embodiments provide a multilayer wiring substrate for a semiconductor package that is able to improve signal transmission characteristics and prevent voids from occurring in a dielectric film on a ball pad.

Example embodiments provide a semiconductor package including the multilayer wiring substrate.

According to example embodiments, a multilayer wiring substrate includes insulating layers sequentially stacked on each other, each of the insulating layers having a respective upper surface and a respective lower surface opposite to the upper surface; circuit layers sequentially stacked and respectively provided in the insulating layers, each of the circuit layers having wirings, one of the circuit layers being a bottommost circuit layer; and lower substrate pads included in the bottommost circuit layer and exposed from the lower surface of the insulating layers, each lower substrate pad of the lower substrate pads being electrically connected to the wirings of at least one circuit layer above the lower substrate pad, the lower substrate pads including a signal ball landing pad, wherein at least one of the circuit layers other than the bottommost circuit layer includes: a respective ground conductive layer at a higher vertical level than the signal ball landing pad and having an opening in a region corresponding to the signal ball landing pad; and a respective signal pattern within the opening of the ground conductive layer, the signal pattern being electrically connected to the signal ball landing pad.

According to example embodiments, a semiconductor package includes a package substrate having upper substrate pads on an upper surface thereof and lower substrate pads on a lower surface thereof, the package substrate including circuit layers sequentially stacked; and at least one semiconductor chip mounted on the upper surface of the package substrate, the at least one semiconductor chip being electrically connected to the upper substrate pads through conductive bumps, wherein the lower substrate pads include a signal ball landing pad, wherein at least one of the circuit layers includes: a respective ground conductive layer on the signal ball landing pad, the ground conductive layer having an opening in a region corresponding to the signal ball landing pad; and a respective signal pattern within the opening of the ground conductive layer, the signal pattern being electrically connected to the signal ball landing pad by at least one conductive via, and wherein the signal pattern overlaps at least 80% of the signal ball landing pad when viewed in plan view.

According to example embodiments, a semiconductor package includes a package substrate having upper substrate pads on an upper surface thereof and lower substrate pads on a lower surface thereof, the package substrate including circuit layers that are sequentially stacked; and at least one semiconductor chip mounted on the upper surface of the package substrate, the at least one semiconductor chip being electrically connected to the upper substrate pads through conductive bumps, wherein the lower substrate pads include a signal ball landing pad, wherein each of the circuit layers includes: a respective ground conductive layer at a higher vertical level than the signal ball landing pad and having an opening in a region corresponding to the signal ball landing pad; and a respective signal pattern within the opening of the ground conductive layer, the signal pattern being electrically connected to the signal ball landing pad, and wherein when viewed in plan view, a diameter of the opening is greater than a diameter of the signal ball landing pad, and the signal pattern overlaps at least 80% of the signal ball landing pad.

According to example embodiments, a multilayer wiring substrate for a semiconductor package may include circuit layers that are sequentially stacked on each other.

The circuit layers may include a plurality of ground conductive layers sequentially disposed on a signal ball landing pad and respectively having openings in regions corresponding to the signal ball landing pad, and a plurality of signal patterns respectively disposed within the openings of the plurality of ground conductive layers and electrically connected to the signal ball landing pad.

The ground conductive layers sequentially disposed on the signal ball landing pad may have the openings in the regions corresponding to the signal ball landing pad respectively, so that capacitances between the signal ball landing pad and the ground conductive layers may be reduced.

Further, the signal patterns sequentially disposed on the signal ball landing pad may be respectively disposed within the openings of the ground conductive layers to form a signal pattern stack. When viewed in plan view, each of the signal patterns may overlap at least 80% of the signal ball landing pad. Since the signal pattern stack sufficiently fills the openings of the ground conductive layers, voids may be prevented from being generated in a dielectric layer on the signal ball landing pad.

Thus, signal transmission characteristics through the package substrate may be improved and voids may be prevented from occurring in the dielectric layer on the signal ball pad.

### BRIEF DESCRIPTION OF THE DRAWINGS

Example embodiments will be more clearly understood from the following detailed description taken in conjunction with the accompanying drawings. FIGS. 1 to 14D represent non-limiting, example embodiments as described herein.

FIG. 1 is a cross-sectional view illustrating a semiconductor package in accordance with example embodiments.

FIG. 2 is a plan view illustrating a portion of an upper surface of a package substrate in FIG. 1.

FIG. 3 is a cross-sectional view taken along the line I-I′ in FIG. 2.

FIGS. 4A to 4E are plan views illustrating portions of circuit layers of the package substrate of FIG. 3.

FIG. 5 is a cross-sectional view illustrating a portion of a package substrate in accordance with a first example embodiment.

FIG. 6 is a plan view illustrating a second circuit layer of the package substrate of FIG. 5.

FIG. 7 is a plan view illustrating a portion of a second circuit layer of a package substrate in accordance with a second example embodiment.

FIG. 8 is a cross-sectional view illustrating a portion of a package substrate according to a comparative example.

FIG. 9A is a plan view illustrating a portion of a first circuit layer of the package substrate of FIG. 8.

FIG. 9B is a plan view illustrating a portion of a second circuit layer of the package substrate of FIG. 8.

FIG. 10 is a graph showing TDR (Time Domain Reflectometry) impedance in semiconductor packages according to a comparative example, a first embodiment, and a second embodiment.

FIG. 11A is a diagram showing an eye diagram in a semiconductor package according to a comparative example.

FIG. 11B is a diagram showing an eye diagram in a semiconductor package according to the first embodiment.

FIG. 11C is a diagram showing an eye diagram in the semiconductor package according to the second embodiment.

FIG. 12 is a cross-sectional view illustrating a semiconductor package in accordance with example embodiments.

FIG. 13 is a cross-sectional view illustrating a portion of a package substrate in FIG. 12.

FIGS. 14A to 14D are plan views illustrating circuit layers of the package substrate of FIG. 13.

### DETAILED DESCRIPTION OF EXAMPLE EMBODIMENTS

Hereinafter, example embodiments will be explained in detail with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise.

The various pads described herein may generally have a planar upper or lower surface having horizontal dimensions (e.g., in a first horizontal direction and in a second horizontal direction perpendicular to the first horizontal direction) that are both larger than wiring to which the pad is connected to facilitate connections thereto (e.g., to provide a larger surface to contact a later formed via). For example, a horizontal wiring may be integrally formed with a pad (e.g., patterned out of the same metal layer) such that the wiring and pad have coplanar upper surfaces, with both of the horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have a symmetrical shape (e.g., a square or rectangular footprint) and may have horizontal dimensions that are about the same (e.g., within half to two times of the other).

Signal pads or terminals or signal solder balls of a device described herein are arranged to receive external signals from outside the device and to transmit internal signals to the outside of the device, and are electrically connected to circuitry within a device that receives, transmits, and processes signals. Ground pads or terminals or ground solder balls of a device described herein are arranged to receive a ground voltage or potential and to supply the ground voltage or potential to circuitry within the device

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same” and “equal” as used herein encompass identicality or near identicality including variations that may occur resulting from conventional manufacturing processes. The term “substantially” may be used herein to emphasize this meaning, unless the context or other statements indicate otherwise.

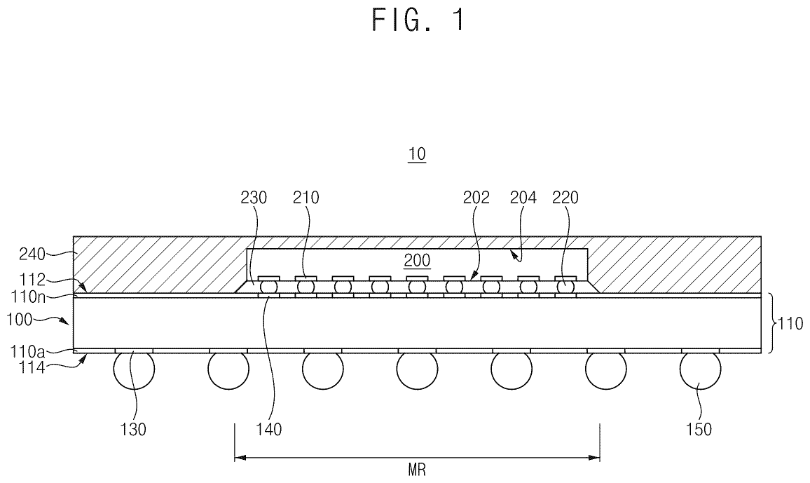

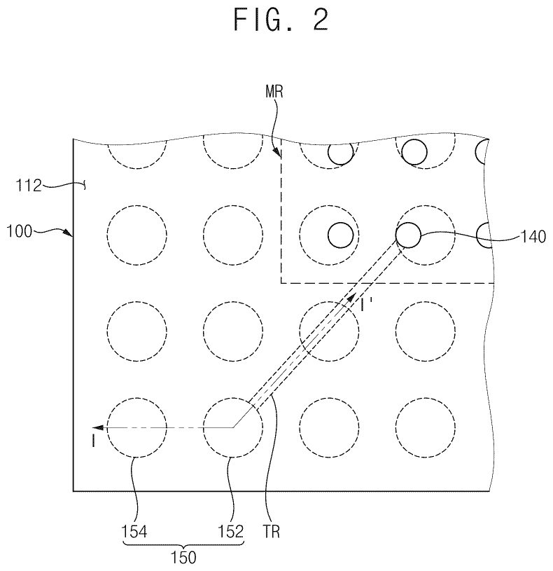

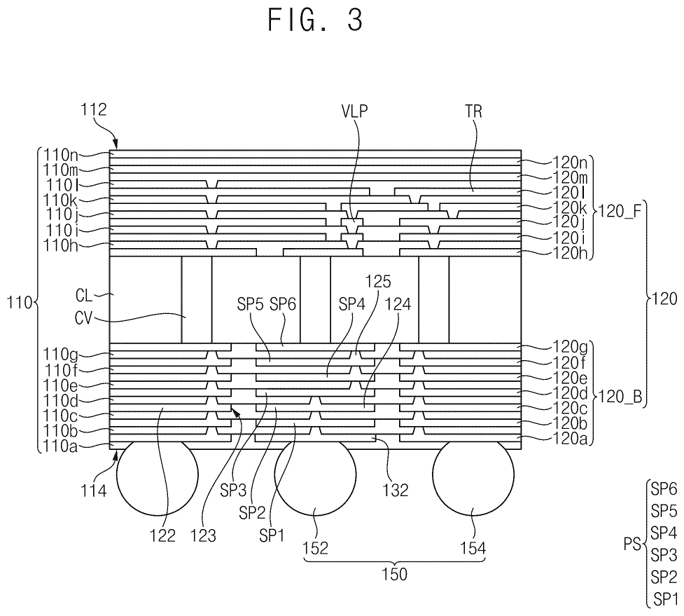

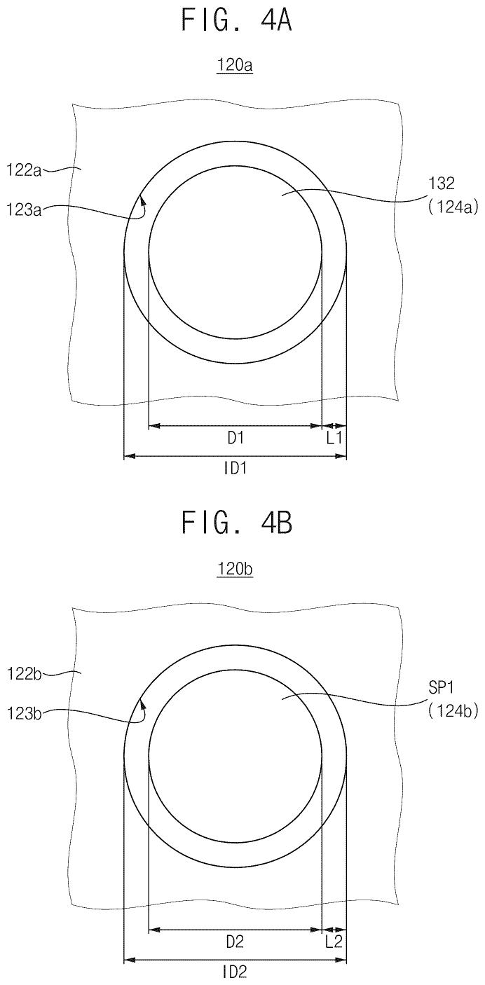

FIG. 1 is a cross-sectional view illustrating a semiconductor package in accordance with example embodiments. FIG. 2 is a plan view illustrating a portion of an upper surface of a package substrate in FIG. 1. FIG. 3 is a cross-sectional view taken along the line I-I′ in FIG. 2. FIGS. 4A to 4E are plan views illustrating portions of circuit layers of the package substrate of FIG. 3.

Referring to FIGS. 1 to 4E, a semiconductor package 10 may include a package substrate 100 and at least one semiconductor chip 200 mounted on the package substrate 100. In addition, the semiconductor package 10 may further include a sealing member 240 on the package substrate 100 and covering the at least one semiconductor chip 200, and solder balls 150 as a plurality of conductive connection members disposed on a lower surface of the package substrate 100.

In example embodiments, the package substrate 100 may be a multilayer wiring substrate having an upper surface 112 and a lower surface 114 opposite to the upper surface 112. The package substrate 100 may include a printed circuit board (PCB), a flexible substrate, a tape substrate, etc. The package substrate 100 may include a plurality of stacked insulating layers 110, and circuit layers 120 each having wirings provided in the insulating layers.

As illustrated in FIG. 3, the package substrate 100 may include a core multilayer substrate.

The package substrate 100 may include a core layer CL, front circuit layers 120_F stacked on a front surface of the core layer CL, and backside circuit layers 120_B stacked on a backside surface of the core layer CL. The core layer CL may include a non-conductive material layer. The core layer CL may include a reinforcing polymer or the like. The core layer CL may serve as a boundary layer dividing an upper portion from a lower portion of the package substrate 100. Core vias CV may be provided in the core layer CL, and the wirings as circuit patterns in the circuit layers 120 may be electrically connected to each other by the core vias CV. A thickness of the package substrate 100 may be within a range of 450 μm to 650 μm. At this time, a thickness of the core layer CL may be within a range of 30 μm to 60 μm.

For example, the package substrate 100 may have 14 circuit layers 120. The package substrate 100 may include first to fourteenth insulating layers 110a, . . . , 110n sequentially stacked. A plurality of circuit layers 120 stacked in a thickness direction from the lower surface 114 to the upper surface 112 of the package substrate 100 may include the wirings therein. The wirings may include ground conductive layers, signal patterns, power patterns, and conductive vias. For example, the wiring may include metal materials such as copper, aluminum, etc. It will be understood that the arrangements and numbers of the insulating layers and the wiring are illustrated as an example, and the inventive concept may not be limited thereto.

A first insulating layer 110a may be formed as a lower protective layer on the lower surface 114 of the package substrate 100, and the first insulating layer 110a may expose at least a portion of a lowermost wiring of a lowermost circuit layer 120a. The exposed portion of the lowermost wiring may serve as a lower substrate pad 130 (see, e.g., FIG. 1). A fourteenth insulating layer 110n may be formed as an upper protective layer on the upper surface 112 of the package substrate 100, and the fourteenth insulating layer 110n may expose at least a portion of an uppermost wiring of an uppermost circuit layer 120n. The exposed portion of the uppermost wiring may serve as an upper substrate pad 140 (see, e.g., FIG. 1).

The lower protective layer 110a and the upper protective layer 110n may separate the circuit patterns of the package substrate 100 from the external environment to prevent contamination and electrically insulate the wirings of the circuit patterns from each other. For example, the upper protective layer and the lower protective layer may include a photosensitive polymer such as photo solder resist (PSR) or a photosensitive resin such as photo epoxy.

As illustrated in FIGS. 1 and 2, a plurality of the upper substrate pads 140 may be arranged in an array form within a mounting region MR on the upper surface 112 of the package substrate 100. A plurality of the lower substrate pads 130 may be arranged in an array form over the entire lower surface 114. The upper substrate pads 140 and the lower substrate pads 130 may be electrically connected to each other through the wirings of the circuit layers 120. A data signal, a power signal, or a ground signal may be transmitted through the lower substrate pads 130, the wirings, and the upper substrate pads 140.

In example embodiments, the semiconductor chip 200 may be disposed on the mounting region MR on the upper surface 112 of the package substrate 100. The semiconductor chip 200 may be mounted on the package substrate 100 using a flip chip bonding method. The semiconductor chip 200 may be mounted on the package substrate 100 via conductive bumps 220. The semiconductor chip 200 may be mounted on the package substrate 100 such that an active surface on which chip pads 210 are formed, that is, the first surface 202, faces the package substrate 100.

In this case, the conductive bumps may include micro bumps (uBump). The conductive bumps may be formed on the chip pads 210, and the conductive bumps may be interposed between the chip pads 210 of the semiconductor chip 200 and the upper substrate pads 140 of the package substrate 100. For example, the conductive bumps may include solder bumps and/or pillar bumps. An underfill member 230 may be underfilled between the semiconductor chip 200 and the package substrate 100. The underfill member 230 may include an epoxy material.

The semiconductor chip may be a logic chip including logic circuits. The logic chip may be a controller that controls memory chips. The semiconductor chip may be a processor chip or an application processor AP such as an ASIC as a host such as CPU, GPU, or SOC.

Alternatively, the semiconductor chip may include a memory chip including a memory circuit. For example, the semiconductor chip may include volatile memory devices such as SRAM devices or DRAM devices, and non-volatile memory devices such as flash memory devices, PRAM devices, MRAM devices or RRAM devices.

In this embodiment, one semiconductor chip is disposed on the package substrate, but the present inventive concept is not limited thereto, and for example, a plurality of semiconductor chips may be sequentially stacked on a package area of the package substrate 100.

The sealing member 240 may be provided on the upper surface 112 of the package substrate 100 to cover at least a portion of the semiconductor chip 200. The sealing member 240 may cover four side surfaces of the semiconductor chip 200. A second surface 204, that is, a backside surface, of the semiconductor chip 200 may be exposed or covered by the sealing member 240. For example, the sealing member 240 may include an epoxy mold compound (EMC). The sealing member 240 may include UV resin, polyurethane resin, silicon resin, silica fillers, etc.

In example embodiments, solder balls 150 as the conductive connection members may be disposed on the lower substrate pads 130 on the lower surface 114 of the package substrate 100, respectively. For example, the solder balls 150 may have a diameter within a range of 300 μm to 600 μm. The solder balls 150 may include a signal solder ball 152 for transmitting a data signal and a ground solder ball 154 for transmitting a ground signal (see, e.g., FIGS. 2 and 3). The lower substrate pads 130 may include a signal ball landing pad 132 on which the signal solder ball 152 is disposed.

As illustrated in FIG. 3, the backside circuit layers 120_B may include a plurality of ground conductive layers 122 that are sequentially disposed on (e.g., at a higher level than) the signal ball landing pad 132 and respectively have openings 123 in regions corresponding to the signal ball landing pad 132, and a plurality of signal patterns 124 respectively disposed within the openings 123 of the plurality of ground conductive layers 122. The plurality of signal patterns 124 may be electrically connected to the signal ball landing pad 132 through conductive vias 125. For example, the plurality of ground conductive layers 122 may be disposed at a higher vertical level than the signal ball landing pad 132. The plurality of ground conductive layers 122 may not be disposed directly above the signal ball landing pad 132 (e.g., may not vertically overlap the signal ball landing pad 132) because the openings 123 are disposed directly above the signal ball landing pad 132.

As illustrated in FIG. 4A, a lowermost circuit layer 120a may include a first ground conductive layer 122a having a first opening 123a and a signal ball landing pad 132 disposed within the first opening 123a. A portion of an outer surface of the signal ball landing pad 132 may be exposed by the first insulating layer 110a, and the signal solder ball 152 may be disposed on the exposed portion of the signal ball landing pad 132. A portion of an outer surface of the first ground conductive layer 122a may be exposed by the first insulating layer 110a, and the ground solder ball 154 may be disposed on the exposed portion of the ground conductive layer 122a. A first diameter D1 of the signal ball landing pad 132 may be smaller than a first diameter ID1 of the first opening 123a. The first diameter D1 of the signal ball landing pad 132 may be within a range of 300 μm to 1,000 μm, and the first diameter ID1 of the first opening 123a may be within a range of 350 μm to 1,120 μm. The signal ball landing pad 132 may be spaced apart from an inner surface of the first opening 123a by a first distance L1, and the first distance L1 may be within a range of 50 μm to 120 μm.

As illustrated in FIG. 4B, a second circuit layer 120b may include a second ground conductive layer 122b having a second opening 123b and a first signal pattern SP1, 124b disposed within the second opening 123b. The second opening 123b may be provided in a region corresponding to the signal ball landing pad 132. The first signal pattern SP1 may partially fill the second opening 123b and may overlap the signal ball landing pad 132 in a vertical direction. The second opening 123b may have a center at the same horizontal position as that of the first opening 123a, and the first signal pattern SP1 may have a center at the same horizontal position as that of the signal ball landing pad 132. When viewed in plan view, the first signal pattern SP1 may overlap at least 80% of the signal ball landing pad 132. The first signal pattern SP1 may have an area equal to an area of the signal ball landing pad 132. Alternatively, the first signal pattern SP1 may have an area greater or less than the area of the signal ball landing pad 132. The first signal pattern SP1 may have a shape the same as the signal ball landing pad 132. The first signal pattern SP1 and the signal ball landing pad 132 may have a circular or oval shape. The first signal pattern SP1 may be spaced apart from an inner surface of the second opening 123b by a second distance L2, and the second distance L2 may be within a range of 50 μm to 120 μm.

As illustrated in FIG. 4C, a third circuit layer 120c may include a third ground conductive layer 122c having a third opening 123c and a second signal pattern SP2, 124c disposed within the third opening 123c. The third opening 123c may be provided in a region corresponding to the signal ball landing pad 132. The second signal pattern SP2 may partially fill the third opening 123c and may overlap the signal ball landing pad 132 in the vertical direction. The third opening 123c may have a center at the same horizontal position as that of the first opening 123a and/or the second opening 123b, and the second signal pattern SP2 may have a center at the same horizontal position as that of the signal ball landing pad 132 and/or the first signal pattern SP1. When viewed in plan view, the second signal pattern SP2 may overlap at least 80% of the signal ball landing pad 132. The second signal pattern SP2 may have an area equal to the area of the signal ball landing pad 132 and/or the first signal pattern SP1. Alternatively, the second signal pattern SP2 may have an area greater or less than the area of the signal ball landing pad 132 or the first signal pattern SP1. The second signal pattern SP2 may have a shape the same as the signal ball landing pad 132 and/or the first signal pattern SP1. The second signal pattern SP2 may have a circular or oval shape.

As illustrated in FIG. 4D, a fourth circuit layer 120d may include a fourth ground conductive layer 122d having a fourth opening 123d and a third signal pattern SP3, 124d disposed within the fourth opening 123d. The fourth opening 123d may be provided in a region corresponding to the signal ball landing pad 132. The third signal pattern SP3 partially fills the fourth opening 123d and may overlap the signal ball landing pad 132 in the vertical direction. The fourth opening 123d may have a center at the same horizontal position as the that of first opening 123a and/or the third opening 123c, and the third signal pattern SP3 may have a center at the same horizontal position as that of the signal ball landing pad 132 and/or the second signal pattern SP2. When viewed in plan view, the third signal pattern SP3 may overlap at least 80% of the signal ball landing pad 132. The third signal pattern SP2 may have an area equal to the area of the signal ball landing pad 132 and/or the second signal pattern SP2. Alternatively, the third signal pattern SP3 may have an area greater or less than the area of the signal ball landing pad 132 or the second signal pattern SP2. The third signal pattern SP3 may have a shape the same as the signal ball landing pad 132 and/or the second signal pattern SP2. The third signal pattern SP3 may have a circular or oval shape.

As illustrated in FIG. 4E, the front circuit layers 120_F may include via landing pads VLP that are sequentially stacked on each other and a trace TR extending in a horizontal direction from at least one of the via landing pads. The via landing pads VLP may be electrically connected to the core via CV by conductive vias, and the trace TR may be electrically connected to the upper substrate pad 140.

The signal patterns 124 may be sequentially disposed on the signal ball landing pad 132 and may be disposed within the openings 123 of the ground conductive layers 122 respectively to form a signal pattern stack PS. The signal patterns 124 may be electrically connected to the signal ball landing pad 132 through the conductive vias 125. For example, the signal ball landing pad 132 may be electrically connected to the first signal pattern SP1 by a single conductive via 125, and the first signal pattern SP1 may be electrically connected to the second signal pattern SP2 by a single conductive via 125. A diameter of the conductive via 125 may be within a range of 40 μm to 80 μm.

As mentioned above, the ground conductive layers 122 sequentially disposed on the signal ball landing pad 132 may have the openings 123 in the region corresponding to the signal ball landing pad 132 respectively, so that capacitances between the signal ball landing pad 132 and the ground conductive layers 122 may be reduced.

The signal patterns 124 sequentially disposed on the signal ball landing pad 132 may be respectively disposed within the openings 123 of the ground conductive layers 122 to form the signal pattern stack PS. When viewed in plan view, each of the signal patterns may overlap at least 80% of the signal ball landing pad 132. Since the signal pattern stack PS sufficiently fills the openings 123 of the ground conductive layers 122, voids may be prevented from being generated in the dielectric layer (e.g., in one or more of the plurality of insulating layers 110) on the signal ball landing pad 132.

Thus, signal transmission characteristics through the package substrate 100 may be improved and voids may be prevented from occurring in the dielectric layer on the signal ball pad 132.

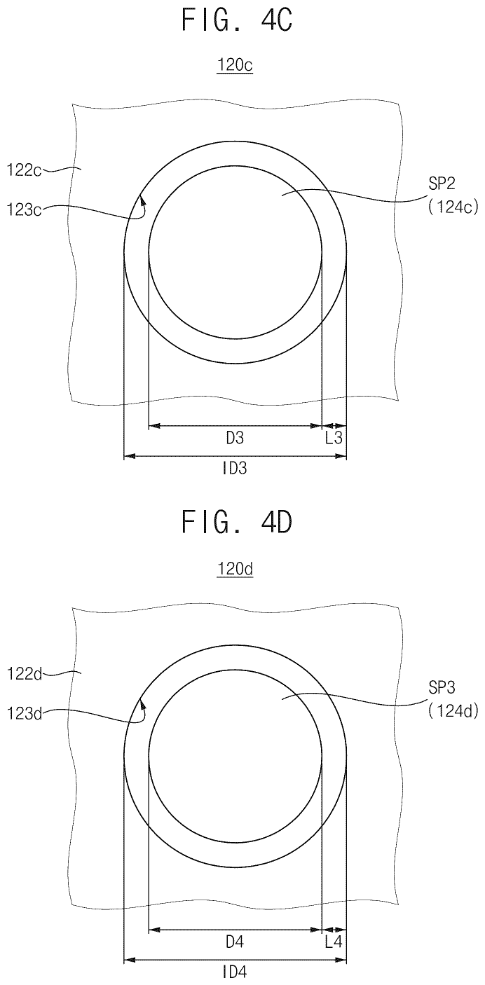

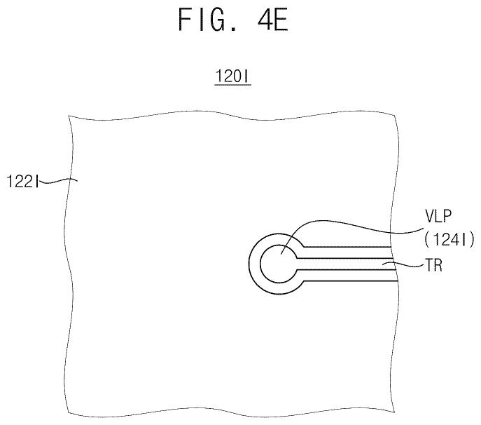

FIG. 5 is a cross-sectional view illustrating a portion of a package substrate according to a first embodiment. FIG. 6 is a plan view illustrating a second circuit layer of the package substrate of FIG. 5.

Referring to FIGS. 5 and 6, signal patterns SP may be sequentially disposed on a signal ball landing pad 132 and may be respectively disposed within openings 123 of ground conductive layers 122 to form a signal pattern stack PS. Each of the signal patterns SP may be electrically connected to the signal ball landing pad 132 by a multi-via structure 125.

As illustrated in FIG. 6, for example, the signal ball landing pad 132 may be electrically connected to a first signal pattern SP1 by four conductive vias 125, and a first signal pattern SP1 may be electrically connected to a second signal pattern SP2 by four conductive vias 125.

Accordingly, the multi-via structure 125 may eliminate or prevent signal characteristic degradation caused by via stubs that occurs when using a single via.

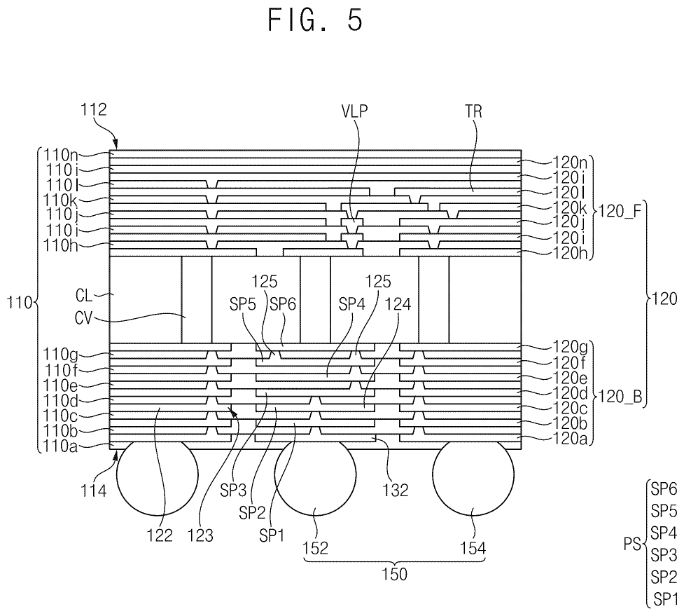

FIG. 7 is a plan view illustrating a portion of a second circuit layer of a package substrate according to a second embodiment.

Referring to FIG. 7, a shape of the opening 123 of at least one ground conductive layer 122 may be expanded. A second opening 123b of a second ground conductive layer 122b may have at least one dent portion DP that is recessed from an inner surface of the second opening 123b. For example, the dent portion DP may be a substantially arc-shaped cutout portion in the edge of the circle formed by the opening 123 when viewed in plan view. For example, four dent portions DP may be spaced apart at equal intervals along a perimeter of the second opening 123b. A spacing distance L2′ between a first signal pattern SP1 and an inner surface of the dent portion DP may be further increased compared to the distance L2 between the first signal pattern SP1 and the inner surface of the second opening 123b according to FIG. 6. The spacing distance L2′ between the first signal pattern SP1 and the inner surface of the dent portion DP may be within a range of 110 μm to 120 μm.

As a space between the first signal pattern SP1 and the inner surface of the dent portion DP is expanded, a capacitance between the first signal pattern SP1 and the second ground conductive layer 122b may be reduced. Accordingly, signal transmission characteristics may be further improved.

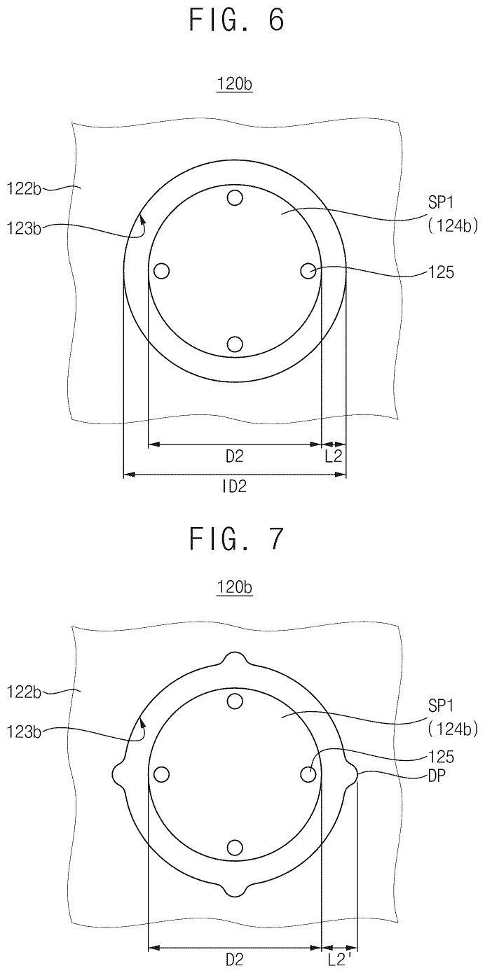

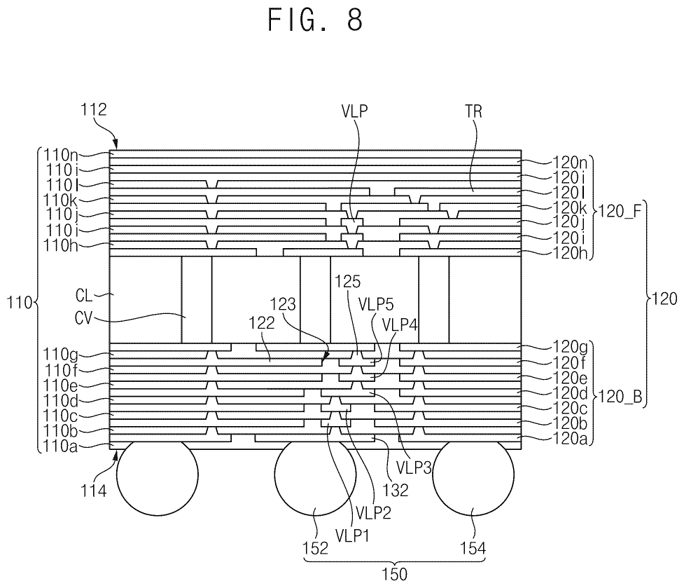

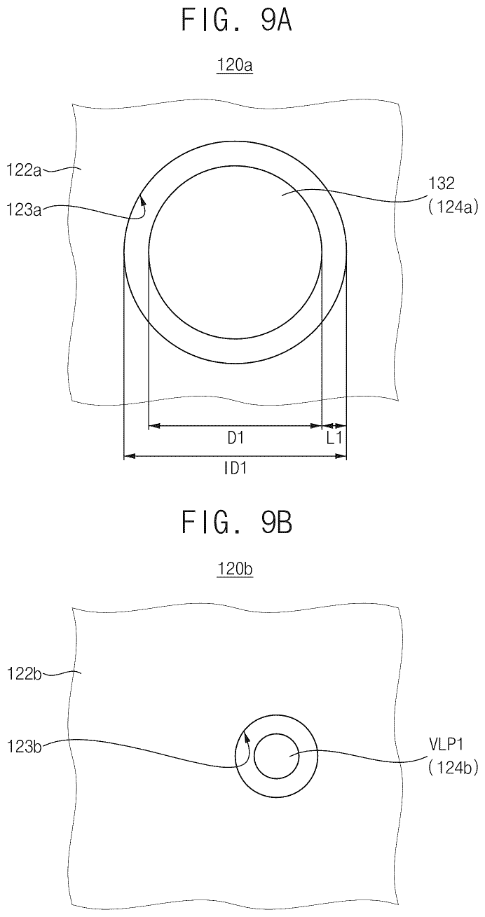

FIG. 8 is a cross-sectional view illustrating a portion of a package substrate according to a comparative example. FIG. 9A is a plan view illustrating a portion of a first circuit layer of the package substrate of FIG. 8, and FIG. 9B is a plan view illustrating a portion of a second circuit layer of the package substrate of FIG. 8.

Referring to FIGS. 8 to 9B, backside circuit layers 120_B may include via landing pads VLP that are sequentially stacked on a signal ball landing pad 132. The via landing pads VLP may be electrically connected to the signal ball landing pad 132 by conductive vias 125.

As illustrating in FIG. 9A, a lowermost circuit layer 120a may include a first ground conductive layer 122a having a first opening 123a and a signal ball landing pad 132 disposed within the first opening 123a. A first diameter D1 of the signal ball landing pad 132 may be smaller than a first diameter ID1 of the first opening 123a. The first diameter D1 of the signal ball landing pad 132 may be within a range of 300 μm to 1,000 μm, and the first diameter ID1 of the first opening 123a may be within a range of 350 μm to 1,120 μm.

As illustrated in FIG. 9B, a second circuit layer 120b may include a second ground conductive layer 122b having a second opening 123b and a first via landing pad VLP1, 124b disposed within the second opening 123b. The second opening 123b may be non-concentric with the first opening 123a, and the first via landing pad VLP1 may be non-concentric with the signal ball landing pad 132. For example, a center of the second opening 123b may not align with the center of the first opening 123a in the vertical direction and the center of the first via landing pad VLP1 may not align with the center of the signal ball landing pad 132 in the vertical direction. The second opening 123b may be provided in a region corresponding to the signal ball landing pad 132. A second diameter D2 of the first via landing pad VLP1 may be within a range of 50 μm to 120 μm. When viewed in plan view, the first via landing pad VLP1 may overlap up to 10% of the signal ball landing pad 132. Accordingly, a portion of the second ground conductive layer 122b may overlap the signal ball landing pad 132, and a capacitance between the signal ball landing pad 132 and the second ground conductive layer 122b may be increased.

According to the comparative example, an impedance of the ball landing pad may be rapidly lowered due to capacitive coupling between the signal ball landing pad 132 and the ground conductive layers 122 on the signal ball landing pad 132, and accordingly, signal reflections may occur and signal quality and insertion loss at high frequencies may deteriorate.

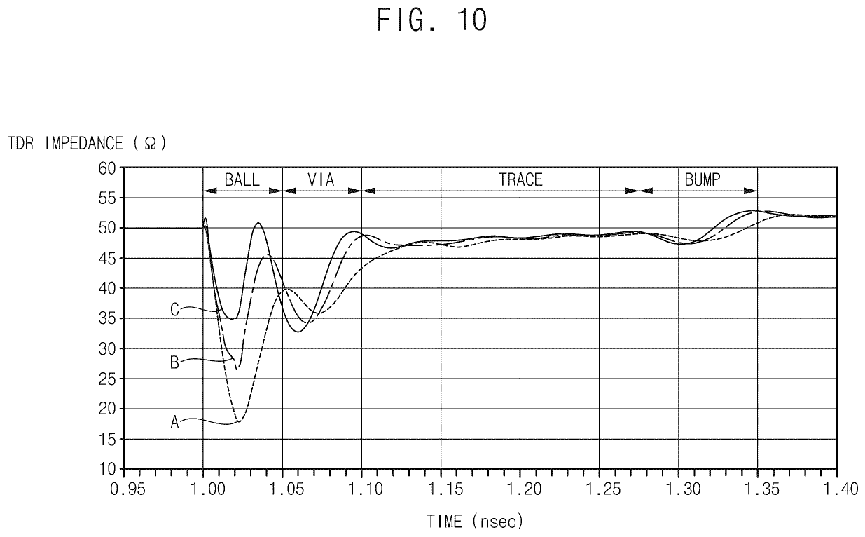

FIG. 10 is a graph showing TDR (Time Domain Reflectometry) impedance in semiconductor packages according to a comparative example, a first embodiment, and a second embodiment.

Referring to FIG. 10, graph A represents the impedance of the package according to the comparative example, graph B represents the impedance of the package according to the first embodiment (the embodiment of FIG. 6), and graph C represents the impedance of the package according to the second embodiment (the embodiment of FIG. 7).

In TDR analysis, as a signal enters the BGA ball from the PCB, the impedance may be measured over time. In graph A, it can be seen that the capacitance in the BGA ball is relatively large, so the impedance (172) is very low. In graph B, it can be seen that a portion of the ground wiring portion on the signal ball pad was removed and signal patterns were placed in the removed space, thereby reducing the capacitance in the signal ball pad and increasing the impedance (2452). In graph C, it can be seen that the space between the signal pattern and the opening is expanded and the capacitance in the signal pattern is reduced, thereby further increasing the impedance (3592).

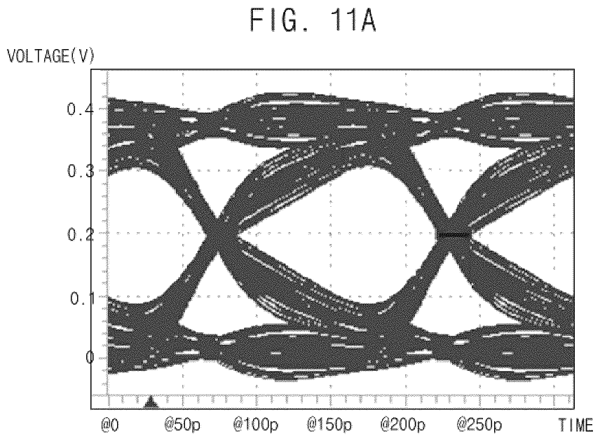

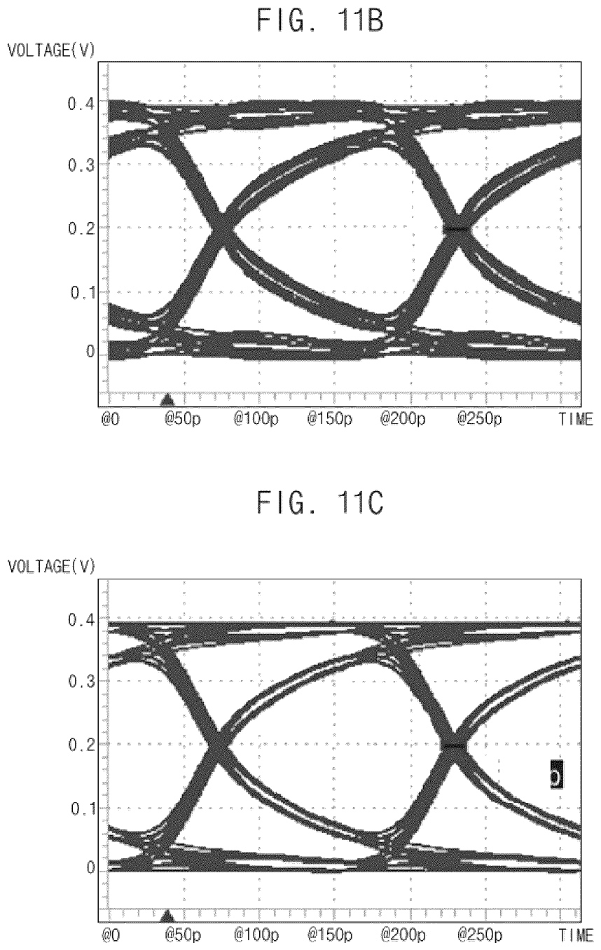

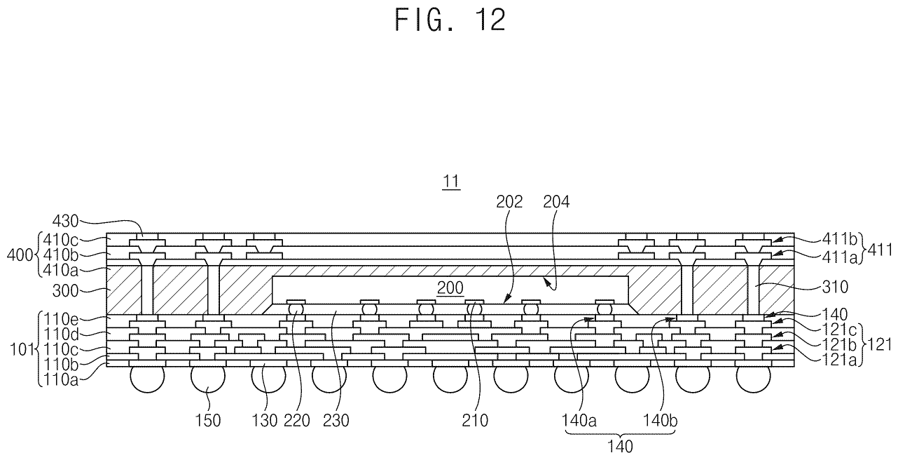

FIG. 11A is an eye diagram in a semiconductor package according to a comparative example, FIG. 11B is an eye diagram in a semiconductor package according to the first embodiment, and FIG. 11C is an eye diagram in the semiconductor package according to the second embodiment.

Referring to FIGS. 11A, 11B, and 11C, the eye opening in the semiconductor package according to the comparative example was 50%, the eye opening in the semiconductor package according to the first embodiment was 63.1%, and the eye opening in the semiconductor package according to the second embodiment was 67.2%. It can be seen that the semiconductor package according to the first embodiment has a larger eye opening than the semiconductor package according to the comparative example, and the semiconductor package according to the second embodiment has a larger eye opening than the semiconductor package according to the first embodiment. The eye diagram may be opened wider as the capacitance at the signal ball pad is reduced and the capacitance at the signal pattern is reduced. A more open eye diagram represents reduced signal distortion.

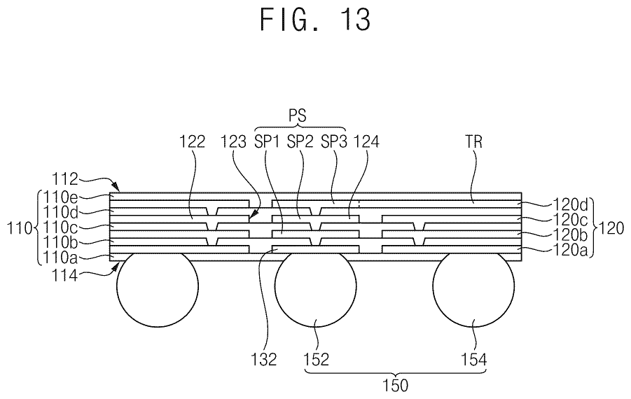

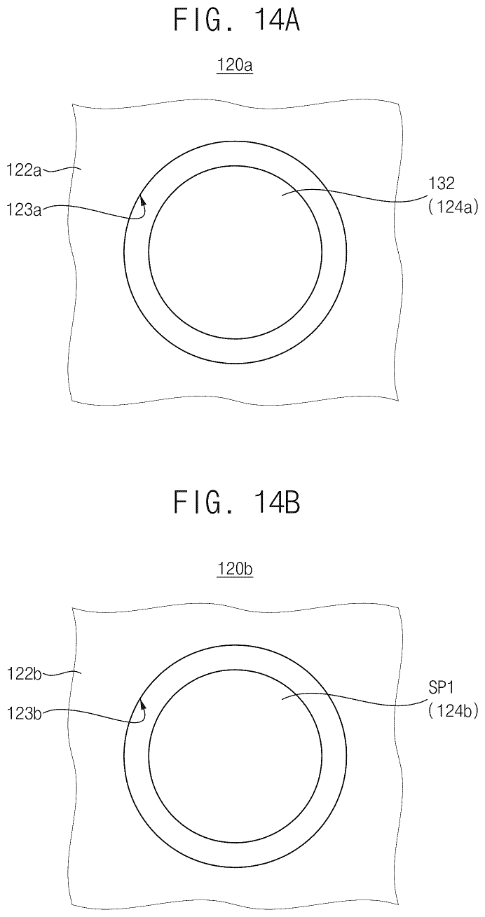

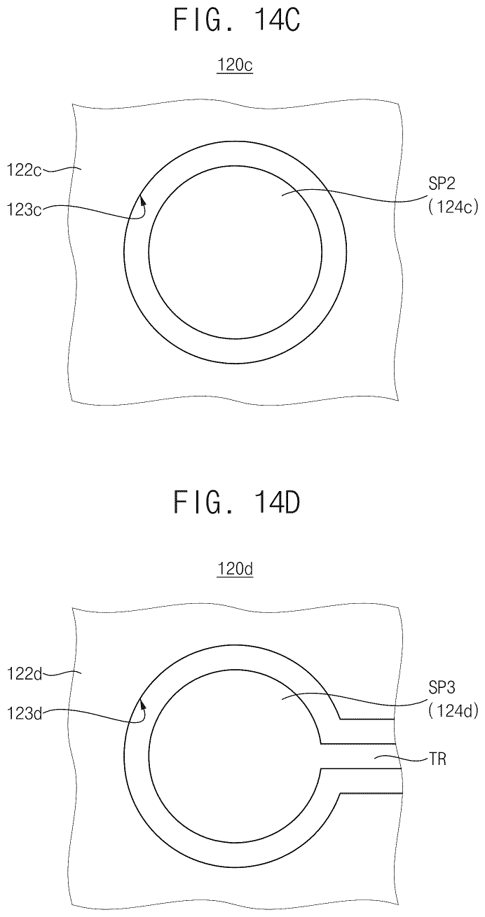

FIG. 12 is a cross-sectional view illustrating a semiconductor package in accordance with example embodiments. FIG. 13 is a cross-sectional view illustrating a portion of a package substrate in FIG. 12. FIGS. 14A to 14D are plan views illustrating circuit layers of the package substrate of FIG. 13. The semiconductor package is substantially the same as the semiconductor package described with reference to FIG. 1 except for a configuration of a semiconductor package. Thus, the same reference numerals will be used to refer to the same or like elements and any further repetitive explanation concerning the above elements will be omitted.

Referring to FIGS. 12 to 14D, a semiconductor package 11 may be a wafer level fan out package or a panel level fan out package. A package substrate of the semiconductor package 11 may include a coreless substrate. A lower redistribution wiring layer 101 as the coreless substrate of the semiconductor package 11 may extend to a sealing member 300 that covers an outer side surface of a semiconductor chip 200. The coreless substrate may be formed by an embedded trace substrate (ETS) method or a wiring process called back-end-of-line (BEOL). Additionally, the semiconductor package 11 may be provided as a unit package on which a second package is stacked on.

Additionally, the semiconductor package 11 may be provided as a system in package (SIP). For example, one or more semiconductor chips may be disposed on the lower redistribution wiring layer 101. The semiconductor chips may include a logic chip including logic circuits and/or a memory chip. The logic chip may be a controller that controls memory chips. The memory chip may include various types of memory circuits, such as DRAM, SRAM, flash, PRAM, ReRAM, FeRAM, or MRAM.

As illustrated in FIG. 12, the semiconductor package 11 may include the lower redistribution wiring layer 101 as the coreless substrate, at least one semiconductor chip 200 mounted on the lower redistribution wiring layer 101, vertical conductive structures 310 on the lower redistribution wiring layer 101 and electrically connected to the at least one semiconductor chip 200, and a sealing member 300 covering the at least one semiconductor chip 200 on the lower redistribution wiring layer 101 and exposing upper end portions of the vertical conductive structures 310, and an upper redistribution wiring layer 400 on the sealing member 300 and electrically connected to the vertical conductive structures 310.

In example embodiments, the lower redistribution wiring layer 101 may be a front redistribution layer (FRDL) of the fan-out package. The lower redistribution wiring layer 101 may include first to fifth lower insulating layers 110a, 110b, 110c, 110d, and 110e and circuit layers 120 having first redistribution wirings 121 in the lower insulating layers. The first redistribution wirings 121 may include first to third lower redistribution wirings 121a, 121b, and 121c that are vertically stacked.

Lower substrate pads 130 may be exposed from a lower surface 114 of the lower redistribution wiring layer 101. Upper substrate pads 140 may be exposed from an upper surface 112 of the lower redistribution wiring layer 101. The upper substrate pads 140 may include first substrate pads 140a disposed in a chip mounting region of the lower redistribution wiring layer 101 and second substrate pads 140b disposed in a fan-out region of the lower redistribution wiring layer 101 surrounding the chip mounting region. The first substrate pads 140a may be arranged in an array form within the chip mounting region on the upper surface 112 of the lower redistribution wiring layer 101. The lower substrate pads 130 may be arranged in an array form over the entire lower surface 114 of the lower redistribution wiring layer 101. The upper substrate pads 140 and the lower substrate pads 130 may be electrically connected to each other through the first redistribution wirings 121. A data signal, a power signal, or a ground signal may be transmitted through the lower substrate pads 130, the first redistribution wirings 121, and the upper substrate pads 140.

The semiconductor chip 200 may be disposed in the chip mounting region, which is the fan-in region of the lower redistribution wiring layer 101. The semiconductor chip 200 may be mounted on the upper surface 112 of the lower redistribution wiring layer 101 using a flip chip bonding method. The semiconductor chip 200 may be disposed such that a front surface 202 on which chip pads 210 are formed, that is, an active surface, faces the lower redistribution wiring layer 101. The chip pads 210 of the semiconductor chip 200 may be electrically connected to the first redistribution wirings 121 of the lower redistribution wiring layer 101 through conductive bumps 220. The conductive bumps 220 may be respectively bonded to the first substrate pads 140a on uppermost first redistribution wirings 121c. For example, the conductive bump 220 may include a micro bump (uBump).

Vertical conductive pillars 310 as the vertical conductive structures may extend upward on the second substrate pads 140b that are positioned in the fan-out region of the lower redistribution layer 101, respectively.

The sealing member 300 may cover the semiconductor chip 200 and the plurality of vertical conductive pillars 310 on the upper surface 112 of the lower redistribution wiring layer 101. The sealing member 300 may expose upper end portions of the vertical conductive pillars 310.

The upper redistribution wiring layer 400 may be disposed on an upper surface of the sealing member 300. The upper redistribution wiring layer 400 may include stacked first to third upper insulating layers 410a, 410b, and 410c and second redistribution wirings 411 in the first to third upper insulating layers 410a, 410b, and 410c. The second redistribution wirings 411 may include first and second upper redistribution wirings 411a and 411b. The upper substrate pads 430 may be respectively disposed on the second upper redistribution wirings 411b as the uppermost redistribution wirings.

In example embodiments, solder balls 150 as conductive connection members may be disposed on the lower substrate pads 130 on the lower surface of the lower redistribution layer 101, respectively. For example, the solder balls 150 may have a diameter within a range of 300 μm to 600 μm. The solder balls 150 may include a signal solder ball 152 for transmitting a data signal and a ground solder ball 154 for transmitting a ground signal (see, e.g., FIG. 13). The lower substrate pads 130 may include a signal ball landing pad 132 on which the signal solder ball 152 is disposed.

As illustrated in FIG. 13, the circuit layers 120 may include a plurality of ground conductive layers 122 that are sequentially disposed on the signal ball landing pad 132 and respectively have openings 123 in regions corresponding to (e.g., above) the signal ball landing pad 132, and a plurality of signal patterns 124 respectively disposed within the openings 123 of the plurality of ground conductive layers 122. The plurality of signal patterns 124 may be electrically connected to the signal ball landing pad 132 through conductive vias 125.

As illustrated in FIG. 14A, a bottom circuit layer 120a may include a first ground conductive layer 122a having a first opening 123a and a signal ball landing pad 132, 124a disposed within the first opening 123a. A portion of an outer surface of the signal ball landing pad 132 (e.g., a bottom surface as shown in FIG. 13) may be exposed by the first insulating layer 110a, and the signal solder ball 152 may be disposed on the exposed portion of the signal ball landing pad 132. A portion of an outer surface of the first ground conductive layer 122a may be exposed by the first insulating layer 110a, and the ground solder ball 154 may be disposed on the exposed portion of the ground conductive layer 122a. A first diameter D1 of the signal ball landing pad 132 may be smaller than a first diameter ID1 of the first opening 123a. The first diameter D1 of the signal ball landing pad 132 may be within a range of 300 μm to 1,000 μm, and the first diameter ID1 of the first opening 123a may be within a range of 350 μm to 1,120 μm. The signal ball landing pad 132 may be spaced apart from an inner surface of the first opening 123a by a first distance L1, and the first distance L1 may be within a range of 50 μm to 120 μm.

As illustrated in FIG. 14B, a second circuit layer 120b may include a second ground conductive layer 122b having a second opening 123b and a first signal pattern SP1, 124b disposed within the second opening 123b. The second opening 123b may be provided in a region corresponding to the signal ball landing pad 132. The first signal pattern SP1 may partially fill the second opening 123b and may overlap the signal ball landing pad 132 in the vertical direction. The second opening 123b may have a center at the same horizontal position as that of the first opening 123a, and the first signal pattern SP1 may have a center at the same horizontal position as that of the signal ball landing pad 132. When viewed in plan view, the first signal pattern SP1 may overlap at least 80% of the signal ball landing pad 132. The first signal pattern SP1 may have an area equal to an area of the signal ball landing pad 132. Alternatively, the first signal pattern SP1 may have an area greater or less than the area of the signal ball landing pad 132. The first signal pattern SP1 may have a shape the same as the signal ball landing pad 132. The first signal pattern SP1 and the signal ball landing pad 132 may have a circular or oval shape. The first signal pattern SP1 may be spaced apart from an inner surface of the second opening 123b by a second distance L2, and the second distance L2 may be within a range of 50 μm to 120 μm.

As illustrated in FIG. 14C, a third circuit layer 120c may include a third ground conductive layer 122c having a third opening 123c and a second signal pattern SP2, 124c disposed within the third opening 123c. The third opening 123c may be provided in a region corresponding to the signal ball landing pad 132. The second signal pattern SP2 may partially fill the third opening 123c and may overlap the signal ball landing pad 132 in the vertical direction. The third opening 123c may have a center at the same horizontal position as that of the first opening 123a and/or the second opening 123b, and the second signal pattern SP2 may have a center at the same horizontal position as that of the signal ball landing pad 132 and/or the first signal pattern SP1. When viewed in plan view, the second signal pattern SP2 may overlap at least 80% of the signal ball landing pad 132. The second signal pattern SP2 may have an area equal to the area of the signal ball landing pad 132 or the first signal pattern SP1. Alternatively, the second signal pattern SP2 may have an area greater or less than the area of the signal ball landing pad 132 or the first signal pattern SP1. The second signal pattern SP2 may have a shape the same as the signal ball landing pad 132 or the first signal pattern SP1. The second signal pattern SP2 may have a circular or oval shape.

As illustrated in FIG. 14D, an uppermost circuit layer 120d may include a fourth ground conductive layer 122d having a fourth opening 123d and a third signal pattern SP3, 124d disposed within the fourth opening 123d. The fourth opening 123d may be provided in a region corresponding to the signal ball landing pad 132. The third signal pattern SP3 may partially fill the fourth opening 123d and may overlap the signal ball landing pad 132 in the vertical direction. The fourth opening 123d may have a center at the same horizontal position as that of the first opening 123a and/or the third opening 123c, and the third signal pattern SP3 may have a center at the same horizontal position as that of the signal ball landing pad 132 and/or the second signal pattern SP2. When viewed in plan view, the third signal pattern SP3 may overlap at least 80% of the signal ball landing pad 132. The third signal pattern SP2 may have an area equal to the area of the signal ball landing pad 132 or the second signal pattern SP2. Alternatively, the third signal pattern SP3 may have an area greater or less than the area of the signal ball landing pad 132 or the second signal pattern SP2. The third signal pattern SP3 may have a shape the same as the signal ball landing pad 132 or the second signal pattern SP2. The third signal pattern SP3 may have a circular or oval shape.

Additionally, the uppermost circuit layer 120d may include a trace TR that extends horizontally from the third signal pattern SP3, 124d. The trace TR may be electrically connected to the upper substrate pad 140.

The first, second, and third signal patterns SP1, SP2, and SP3 may be sequentially disposed on the signal ball landing pad 132 and may be disposed within the openings 123b, 123c, and 123d of the second, third, and fourth ground conductive layers 122b, 122c, and 122d, respectively, to form a signal pattern stack PS.

For example, the lower redistribution layer 101 as the package substrate may include a first number (3) of circuit layers 120b, 120c, and 120d that are sequentially stacked on the signal ball landing pad 132. The same first number (3) of signal patterns SP1, SP2, and SP3 may be respectively provided in the first number (3) of circuit layers and may be sequentially stacked.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments.

What is claimed is:

1. A multilayer wiring substrate, comprising:
insulating layers sequentially stacked on each other, each of the insulating layers having a respective upper surface and a respective lower surface opposite to the upper surface;
circuit layers sequentially stacked and respectively provided in the insulating layers, each of the circuit layers having wirings, one of the circuit layers being a bottommost circuit layer; and
lower substrate pads included in the bottommost circuit layer and exposed from the lower surface of the insulating layers, each lower substrate pad of the lower substrate pads being electrically connected to the wirings of at least one circuit layer above the lower substrate pad, the lower substrate pads including a signal ball landing pad,
wherein at least one of the circuit layers other than the bottommost circuit layer includes:
a respective ground conductive layer at a higher vertical level than the signal ball landing pad and having an opening in a region corresponding to the signal ball landing pad; and
a respective signal pattern within the opening of the ground conductive layer, the signal pattern being electrically connected to the signal ball landing pad.

2. The multilayer wiring substrate of claim 1, wherein the multilayer wiring substrate includes a core layer, and
the circuit layers include a plurality of front circuit layers on a front surface of the core layer and a plurality of backside circuit layers on a backside surface of the core layer.

3. The multilayer wiring substrate of claim 2, wherein each of the plurality of backside circuit layers includes a respective ground conductive layer and a respective signal pattern.

4. The multilayer wiring substrate of claim 1, wherein when viewed in plan view, the signal pattern overlaps at least 80% of the signal ball landing pad.

5. The multilayer wiring substrate of claim 1, wherein an area of the signal pattern is within a range of 80% to 120% of an area of the signal ball landing pad.

6. The multilayer wiring substrate of claim 1, wherein the signal pattern is spaced apart from an inner surface of the corresponding opening by a first distance, and the first distance is within a range of 50 μm to 120 μm.

7. The multilayer wiring substrate of claim 1, wherein the signal ball landing pad has a diameter within a range of 300 μm to 1,000 μm.

8. The multilayer wiring substrate of claim 1, wherein a plurality of the signal patterns are respectively included in a plurality of the circuit layers, and wherein the plurality of signal patterns are electrically connected to each other by conductive vias.

9. The multilayer wiring substrate of claim 8, wherein each of the conductive vias has a diameter within a range of 40 μm to 80 μm.

10. The multilayer wiring substrate of claim 1, wherein a first number of the circuit layers are sequentially stacked on the signal ball landing pad, and the first number of the signal patterns are respectively provided in the first number of the circuit layers and are sequentially stacked.

11. A semiconductor package, comprising:
a package substrate having upper substrate pads on an upper surface thereof and lower substrate pads on a lower surface thereof, the package substrate including circuit layers sequentially stacked; and
at least one semiconductor chip mounted on the upper surface of the package substrate, the at least one semiconductor chip being electrically connected to the upper substrate pads through conductive bumps,
wherein the lower substrate pads include a signal ball landing pad,
wherein at least one of the circuit layers includes:
a respective ground conductive layer on the signal ball landing pad, the ground conductive layer having an opening in a region corresponding to the signal ball landing pad; and
a respective signal pattern within the opening of the ground conductive layer, the signal pattern being electrically connected to the signal ball landing pad by at least one conductive via, and
wherein the signal pattern overlaps at least 80% of the signal ball landing pad when viewed in plan view.

12. The semiconductor package of claim 11, wherein the package substrate includes a core layer, and
the circuit layers include a plurality of front circuit layers on a front surface of the core layer and a plurality of backside circuit layers on a backside surface of the core layer.

13. The semiconductor package of claim 12, wherein each of the plurality of backside circuit layers includes a respective ground conductive layer and a respective signal pattern.

14. The semiconductor package of claim 11, wherein the signal pattern is spaced apart from an inner surface of the opening by a first distance, and the first distance is within a range of 50 μm to 120 μm.

15. The semiconductor package of claim 11, wherein the opening of the ground conductive layer further includes a dent portion that is recessed from an inner surface of the opening when viewed in plan view.

16. The semiconductor package of claim 11, wherein the conductive via has a diameter within a range of 40 μm to 80 μm.

17. The semiconductor package of claim 11, wherein the package substrate includes a first number of the circuit layers sequentially stacked on the signal ball landing pad, and a first number of the signal pattern are respectively provided in the first number of the circuit layers and sequentially stacked.

18. The semiconductor package of claim 11, further comprising:
a sealing member covering the at least one semiconductor chip on the upper surface of the package substrate.

19. The semiconductor package of claim 11, further comprising:
solder balls respectively disposed on the lower substrate pads on the lower surface of the package substrate.

20. A semiconductor package, comprising:
a package substrate having upper substrate pads on an upper surface thereof and lower substrate pads on a lower surface thereof, the package substrate including circuit layers that are sequentially stacked; and
at least one semiconductor chip mounted on the upper surface of the package substrate, the at least one semiconductor chip being electrically connected to the upper substrate pads through conductive bumps,
wherein the lower substrate pads include a signal ball landing pad,
wherein each of the circuit layers includes:
a respective ground conductive layer at a higher vertical level than the signal ball landing pad and having an opening in a region corresponding to the signal ball landing pad; and
a respective signal pattern within the opening of the ground conductive layer, the signal pattern being electrically connected to the signal ball landing pad, and
wherein when viewed in plan view, a diameter of the opening is greater than a diameter of the signal ball landing pad, and the signal pattern overlaps at least 80% of the signal ball landing pad.
